(19) United States
(12) Patent Application Publication
(10) Pub. No.: US 2003/0189227 A1
(43) Pub. Date: Oct. 9, 2003

(54) High speed SOI transistors

(75) Inventors: Michael S. Liu, Bloomington, MN (US); Shankar P. Sinha, Redwood City, CA (US); Jane Kathleen Rekstad, Maple Grove, MN (US); Paul S. Fechner, Plymouth, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 10/116,295

(22) Filed: Apr. 4, 2002

(51) Int. Cl. H01L 27/01; H01L 27/12; H01L 31/0392

(52) U.S. Cl. 257/347

(57) ABSTRACT

An SOI GAA device is created by etching a buried oxide layer of an SOI wafer structure that is provided over a silicon substrate. A portion of the buried oxide layer remains over the silicon substrate after etching. A plurality of silicon fingers is formed so that the silicon fingers extend over the remaining buried oxide layer. A gate oxide is formed all around each of the silicon fingers, and a common silicon gate is formed all around all of the gate oxides. A common source and a common drain are formed by suitably doping opposite ends of the silicon fingers leaving a channel therebetween.

### TECHNICAL FIELD OF THE INVENTION

The present invention relates to a high speed silicon-on-insulator (SOI) transistor.

### BACKGROUND OF THE INVENTION

An SOI transistor typically consists of a buried insulation layer formed over a silicon substrate, and a silicon layer formed over the buried insulation layer. The insulation making up the buried insulation layer may be, for example, an oxide such as a silicon dioxide or a nitride such as silicon nitride. The silicon layer of the SOI structure is suitably doped to form a source and a drain on either side of a channel of the SOI transistor. A gate oxide is provided over the channel, and a silicon is provided over the gate oxide to form the gate of the SOI transistor.

The small-charge collection volume and p-n junction area of the SOI transistor give it an advantage over its bulk silicon counterparts with respect to single event upsets (SEU) and dose rate effects. A single event upset is a phenomenon in which a localized photo-current pulse is produced by a charged particle that is incident on the sensitive node of the SOI transistor. This pulse causes the SOI transistor to upset when the collected charge is larger than the critical charge.

The resistance of an SOI transistor to single event upsets and dose rate effects can be improved by increasing the critical charge, and the critical charge can be increased by incorporating large cross coupling resistors and/or capacitors in order to increase the RC time constant of the SOI transistor. Cross coupling resistors have typically been formed from polysilicon implanted with arsenic ions. Such a resistor, however, is difficult to control.

Because a capacitor is easier to control, a decrease in the value of the resistor and an increase in the value of the capacitor have been proposed. The decrease in the value of the resistor and the increase in the value of the capacitor are matched so as to keep the RC time constant the same. However, although the capacitor is easier to control, the capacitor takes up too much IC area.

On the other hand, a gate-all-around (GAA) transistor, which has been described by J. P. Colinge, has a large inherent capacitor as part of the gate structure. This capacitor is more easily controlled and it does not require additional IC area.

FIGS. 1, 2, and 3 show a known GAA transistor 10. The GAA transistor 10 is an SOI transistor having a buried oxide 12 typically formed over a silicon substrate 14. The buried oxide 12 is the insulation layer, typically silicon dioxide, of an SOI structure. A gate 16, typically formed from polysilicon, is wrapped around a gate oxide 18 that, in turn, is wrapped around a silicon finger 20. The silicon layer of the SOI structure is etched to form the finger 20. The silicon finger 20 forms a channel 22 for the GAA transistor 10. The silicon finger 20 is suitably doped to form a source 24 and a drain 26 on either side of the channel 22. As viewed in FIG. 1, the source 24 and the drain 26 of the GAA transistor 10 are in front of and behind the gate 16.

The GAA transistor 10 is usually fabricated using an SOI CMOS process to which two process steps are added: a photolithographic step and a wet etch step during which a cavity is formed around the previously patterned silicon finger 20. The gate oxide 18 is then grown around the silicon finger 20, and polysilicon is deposited around the gate oxide 18 to form the gate 16. There are at least two remarkable features of the GAA transistor 10. First, the GAA transistor 10 has essentially two channels (one at the top of the silicon finger 20, and one at the bottom of the silicon finger 20). Second, the entire channel 22 as provided by the silicon finger 20 is surrounded by the gate oxide 18 and the gate 16.

The GAA transistor 10 is extremely insensitive to heavy-ion irradiation and is quite resistant to total-dose gamma irradiation. Also, of all SOI transistors, the GAA transistor 10 presents the smallest leakage current and the smallest threshold voltage dependence on temperature.

During etching to form the silicon finger 20 of the GAA transistor 10, the buried oxide 12 is typically completely off at an active region 28 of the GAA transistor 10, as shown in FIG. 1. A large over-lap of the drain and gate regions results from this etching. Moreover, during formation of the gate oxide 18 of the GAA transistor 10, a thin oxide forms on the silicon substrate 14 in the active region 28 where the buried oxide 12 was removed. This thin oxide on the silicon substrate 14 results in a large capacitance compared to the normal gate oxide capacitance of an MOS field effect transistor. The large drain-gate overlap and the large substrate capacitance in the active region 28 degrade the speed performance of the GAA transistor 10.

The present invention is directed to a GAA device that overcomes one or more of the problems of the prior art.

### SUMMARY OF THE INVENTION

In accordance with one aspect of the present invention, a gate-all-around device comprises a silicon substrate, an SOI structure over the silicon substrate, a plurality of silicon fingers, a gate dielectric, and a gate silicon. The SOI structure includes a buried insulation layer. The plurality of silicon fingers extends over the buried insulation layer. The gate dielectric wraps all around each of the silicon fingers, and the gate silicon wraps all around each of the gate dielectrics to form a common gate.

In accordance with another aspect of the present invention, a method of forming an SOI GAA transistor comprises the following: etching a buried oxide layer of an SOI structure so that a portion of the buried oxide layer remains; forming a silicon finger extending over the portion of the buried oxide layer remaining after etching; forming a gate oxide all around the silicon finger; forming a silicon gate all around the gate oxide; and, forming a source and a drain in the silicon finger.

In accordance with still another aspect of the present invention, a method of forming an SOI GAA device comprises the following: etching a buried oxide layer of an SOI structure so that a portion of the buried oxide layer remains over a silicon substrate; forming a plurality of silicon fingers from a silicon layer of the SOI structure such that the silicon fingers are suspended over the remaining buried oxide layer; forming a gate oxide all around each of the silicon fingers; forming a common silicon gate all around all of the gate oxides; and, forming a common source and a common drain, wherein the common source and the common drain are formed on opposing ends of the silicon fingers.

### BRIEF DESCRIPTION OF THE DRAWINGS

These and other features and advantages will become more apparent from a detailed consideration of the invention when taken in conjunction with the drawings in which:

FIG. 1 illustrates a known GAA transistor;

FIG. 2 is an isometric view of the gate area of the GAA transistor illustrated in FIG. 1;

FIG. 3 is a cross-sectional side view of the gate area shown in FIG. 2;

FIG. 4 illustrates a GAA device according to one embodiment of the present invention;

FIG. 5 is a cross section taken along line 5-5 of FIG. 4; and,

FIG. 6 is a cross section taken along line 6-6 of FIG. 4.

### DETAILED DESCRIPTION

A GAA device 40 according to one embodiment of the present invention is shown in FIG. 4 and comprises a plurality of gate areas 42 formed in cavities of the silicon layer 44 of a silicon-on-insulator (SOI) wafer. As described below, the GAA device 40, in essence, is comprised of a plurality of GAA transistors, where the sources of all transistors are coupled together, where the drains of all of the GAA transistors are coupled together, and where the gates of all transistors are coupled together. Therefore, these GAA transistors are coupled in parallel to effectively form a single transistor.

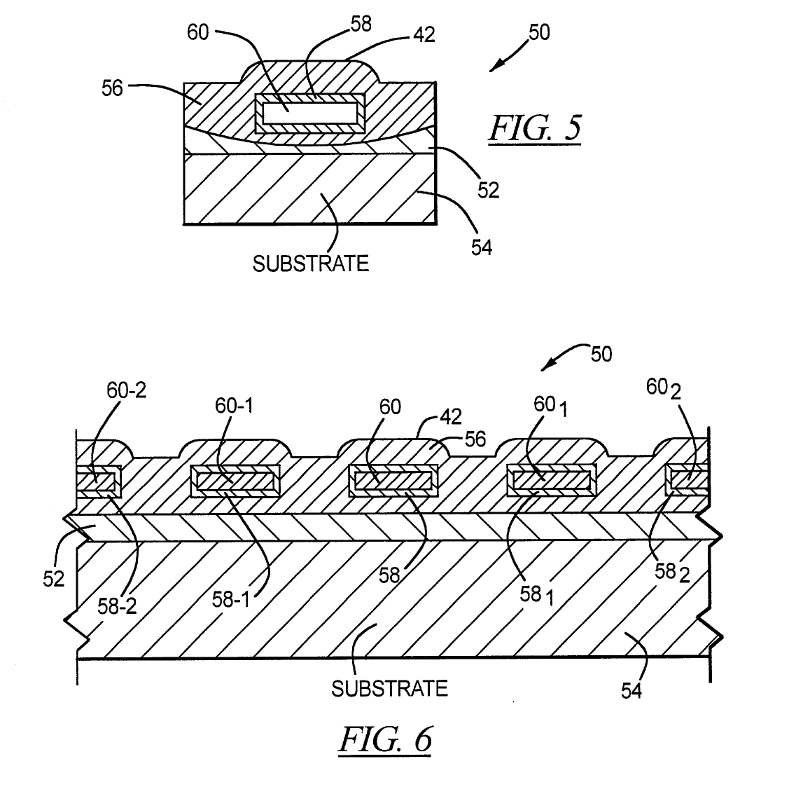

One of the GAA transistors of the GAA device 40 is shown in FIG. 5. This transistor is designated by the reference numeral 50, and the GAA transistor 50 is an SOI transistor having a buried oxide 52 formed over a silicon substrate 54. The buried oxide 52 is the insulation layer, typically silicon dioxide, of the SOI wafer discussed above. However, this insulation layer may be formed from other materials, such as silicon nitride.

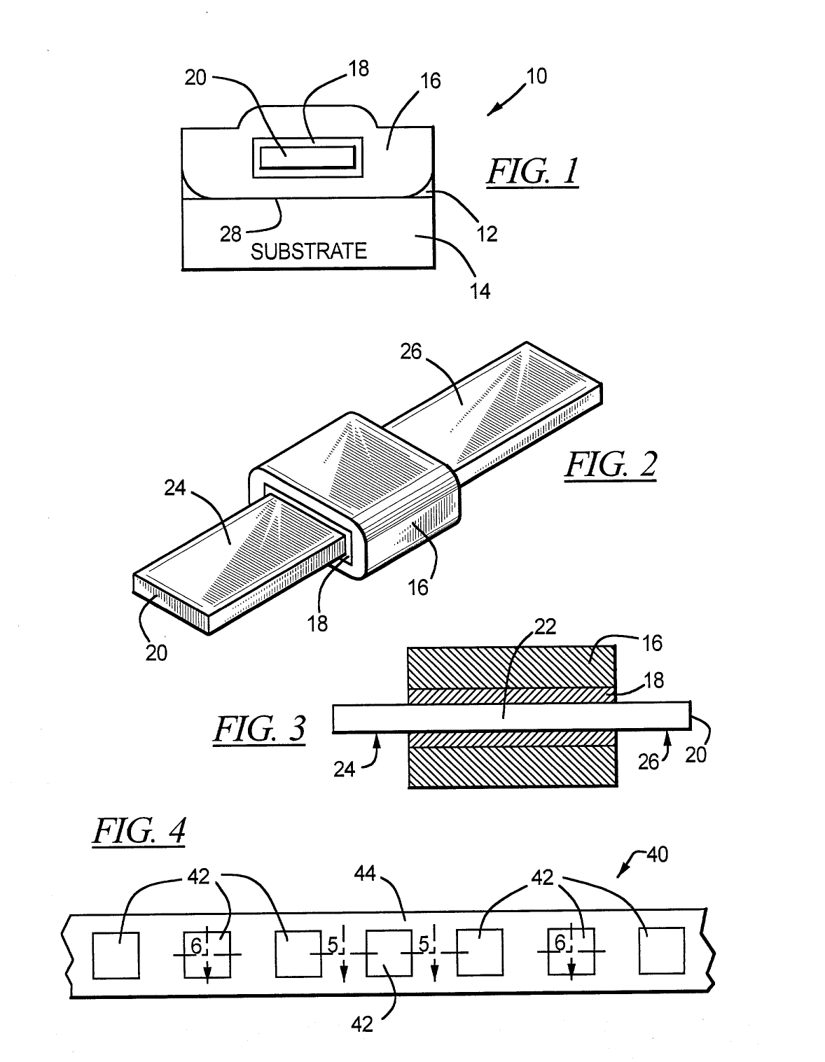

A gate 56 is formed in a corresponding cavity of the silicon layer 44 so that the gate wraps all around a gate oxide 58 that, in turn, wraps all around a silicon finger 60. The gate 56 may be formed of polysilicon. The silicon finger 60 forms the channel, source, and drain of the GAA transistor 50. As in the case of the finger 20 shown in FIGS. 1, 2, and 3, the front and back of the finger 60 (as view in FIG. 5) are suitably doped to form a source and a drain for the GAA transistor 50. The portion of the finger 60 between this source and this drain is the channel of the GAA transistor 50. The channel of the GAA transistor 50 is surrounded by the gate 16 and the gate oxide 58.

Because the GAA device 40 is provided with multiple parallel gates, and by controlling the dimensions of the GAA device 40 such that the combined width/length ratio of all gates approaches the same width/length ratio of the gate of a single GAA transistor known in the prior art, the large drain/gate overlap associated with the GAA transistor 10 discussed above is materially reduced. For example, the combined width/length ratio of the GAA device 40 may be on the order of about twice or more of the width/length ratio of a single known the GAA transistor. Therefore, the overlap capacitance of the GAA transistor 10 is also materially reduced.

Moreover, as discussed above, the buried oxide 12 is etched completely off at the active region 28 of the GAA transistor 10, as shown in FIG. 1. However, during formation of the gate oxide 18 of the GAA transistor 10, a thin oxide forms on the silicon substrate 14 in the active region 28. This thin oxide on the silicon substrate 14 results in a large capacitance as compared to the normal gate oxide capacitance of a typical field effect transistor. This large substrate capacitance may be avoided by making the buried oxide 52 thick and by controlling etching so that the buried oxide 52 is only partially etched, leaving a portion of the buried oxide 52 remaining on the silicon substrate 54 under the channel. For example, the thickness of the buried oxide 52 that is allowed to remain after etching is terminated may be greater than 200 Å and may be on the order of 300 Å to 500 Å. This oxide on the silicon substrate 54 is then made even thicker when the gate oxide 58 is formed. Accordingly, the ultimate capacitance contributed by the oxide on the silicon substrate 54 of the GAA transistor 50 is much smaller than the capacitance contributed by the gate oxide 58.

By materially reducing the drain/gate overlap associated with the GAA transistor 50 as compared to the GAA transistor 10, and by limiting the capacitance contributed by the silicon substrate 54 of the GAA transistor 50 as compared to the GAA transistor 10, the speed performance of the GAA transistor 50 is enhanced as compared to the GAA transistor 10.

As shown in FIG. 6, the buried oxide 52, the silicon substrate 54, and the gate 56 are common to the GAA device 40. Moreover, the drains formed in the silicon fingers 60₋ₙ, . . . , 60₋₁, 60, 60₁, . . . 60ₙ, may be coupled together by any suitable means to form a common drain of the GAA device 40, and the sources formed in the silicon fingers 60₋ₙ, . . ., 60₋₁, 60, 60₁, . . . 60ₙ, may be coupled together by any suitable means to form a common source of the GAA device 40. Separate gate oxides 58₋ₙ, . . ., 58_{-1, 58, 58}₁, . . . 58ₙ correspondingly surround the silicon fingers 60₋ₙ, . . ., 60₋₁, 60, 60₁, . . . 60ₙ, to form GAA transistors 50₋ₙ, . . . 50₋₁, 50, 50₁, . . ., 50ₙ, all of which are coupled in parallel. With this structure, the GAA device 40 is capable of effective SEU resistance without adding external SEU resistant elements. The overall capacitance Ct of a six transistor SRAM cell using this configuration is Ct≧3Cox, where Cox is the gate oxide capacitance of a typical MOS field effect transistor. The amount by which the overall capacitance Ct exceeds 3Cox depends on the desired speed and SEU requirements, and is easily controlled by controlling the layout of the active regions under the GAA transistors 50₋ₙ, . . . 50₋₁, 50, 50₁, . . ., 50ₙ.

For total dose hardness, the sensitive element of the GAA device 40 is the gate oxide, because the buried oxide and the field oxide are not in direct contact with the GAA device. Total dose hardness is assured because of the thin gate oxides 58₋ₙ, . . ., 58₋₁, 58, 58₁, . . ., 58ₙ used around the silicon fingers 60₋ₙ, . . 60₋₁, 60, 60₁, . . . , 60ₙ.

Certain modifications of the present invention have been discussed above. Other modifications will occur to those practicing in the art of the present invention. For example, as described above, a gate oxide is used in the formation of the gates of the GAA device 40. Instead, other dielectrics could be used in place of an oxide.

Moreover, as described above, polysilicon is used as the material from which the gates of the GAA device 40 are formed. Instead, single crystal silicon could be used as the material from which the gates of the GAA device 40 are formed.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

We claim:

1. A gate-all-around device comprising:
a silicon substrate;
an SOI structure over the silicon substrate, wherein the SOI structure includes a buried insulation layer;
a plurality of silicon fingers extending over the buried insulation layer;
a gate dielectric wrapped all around each of the silicon fingers; and,
a gate silicon wrapped all around each of the gate dielectrics to form a common gate.

2. The gate-all-around device of claim 1 wherein the buried insulation layer comprises a buried oxide layer.

3. The gate-all-around device of claim 1 wherein the gate dielectric comprises a gate oxide.

4. The gate-all-around device of claim 3 wherein the buried insulation layer comprises a buried oxide layer.

5. The gate-all-around device of claim 1 wherein the gate silicon comprises polysilicon.

6. The gate-all-around device of claim 5 wherein the buried insulation layer comprises a buried oxide layer.

7. The gate-all-around device of claim 5 wherein the gate dielectric comprises a gate oxide.

8. The gate-all-around device of claim 7 wherein the buried insulation layer comprises a buried oxide layer.

9. The gate-all-around device of claim 1 further comprising a common drain and a common source for the plurality of silicon fingers.

10. The gate-all-around device of claim 9 wherein the buried insulation layer comprises a buried oxide layer.

11. The gate-all-around device of claim 9 wherein the gate dielectric comprises a gate oxide.

12. The gate-all-around device of claim 11 wherein the buried insulation layer comprises a buried oxide layer.

13. The gate-all-around device of claim 9 wherein the gate silicon comprises polysilicon.

14. The gate-all-around device of claim 13 wherein the buried insulation layer comprises a buried oxide layer.

15. The gate-all-around device of claim 13 wherein the gate dielectric comprises a gate oxide.

16. The gate-all-around device of claim 15 wherein the buried insulation layer comprises a buried oxide layer.

17. The gate-all-around device of claim 1 wherein the gates formed by the gate silicon and the gate dielectrics have a combined width/length ratio of about twice that of a single known device.

18. The gate-all-around device of claim 15 wherein the buried insulation layer has a thickness greater than about 200 Å.

19. The gate-all-around device of claim 15 wherein the buried insulation layer has a thickness greater than about 300 Å.

20. A method of forming an SOI GAA transistor comprising:
etching a buried oxide layer of an SOI structure so that a portion of the buried oxide layer remains;
forming a silicon finger extending over the portion of the buried oxide layer remaining after etching;
forming a gate oxide all around the silicon finger;
forming a silicon gate all around the gate oxide; and,
forming a source and a drain in the silicon finger.

21. The method of claim 20 wherein the formation of the silicon finger comprises forming the silicon finger from a silicon layer of the SOI structure.

22. The method of claim 20 wherein the silicon gate comprises a polysilicon gate.

23. The method of claim 20 wherein the buried oxide layer remaining after etching has a thickness greater than about 200 Å.

24. The method of claim 20 wherein the buried oxide layer remaining after etching has a thickness greater than about 300 Å.

25. A method of forming an SOI GAA device comprising:
etching a buried oxide layer of an SOI structure so that a portion of the buried oxide layer remains over a silicon substrate;
forming a plurality of silicon fingers from a silicon layer of the SOI structure such that the silicon fingers are suspended over the remaining buried oxide layer;
forming a gate oxide all around each of the silicon fingers;
forming a common silicon gate all around all of the gate oxides; and,
forming a common source and a common drain, wherein the common source and the common drain are formed on opposing ends of the silicon fingers.

26. The method of claim 25 wherein the common silicon gate comprises a common polysilicon gate.

27. The method of claim 25 wherein the formation of the common source and the common drain comprises forming the common source and the common drain in the silicon fingers.

28. The method of claim 25 wherein the buried oxide layer remaining after etching has a thickness greater than about 200 Å.

29. The method of claim 25 wherein the buried oxide layer remaining after etching has a thickness greater than about 300 Å.

30. The method of claim 25 wherein the common silico n gate has a width/length ratio of about twice that of a single known device.
